(19) United States
(12) Patent Application Publication
(10) Pub. No.: US 2010/0143232 A1
(43) Pub. Date: Jun. 10, 2010

(54) METAL BINARY AND TERNARY COMPOUNDS PRODUCED BY CATHODIC ARC DEPOSITION

(76) Inventors: Benedict James Costello, Berkeley, CA (US); Jeremy Frank, San Francisco, CA (US); Vladimier Gelfandbein, Mountain View, CA (US)

Correspondence Address: Proteus Biomedical, Inc.;Bozicevic, Field & Francis LLP, 1900 University Avenue, Suite 200, East Palo Alto, CA, 94303, US

(21) Appl. No.: 12/305,910

(22) PCT Filed: Jun. 21, 2007
(86) PCT No.: PCT/US07/14505

§ 371 Date: Feb. 2, 2010

Related U.S. Application Data
(60) Provisional application No. 60/805,464, filed on Jun. 21, 2006.
(60) Provisional application No. 60/805,578, filed on Jun. 22, 2006.
(60) Provisional application No. 60/805,576, filed on Jun. 22, 2006.
(60) Provisional application No. 60/805,581, filed on Jun. 22, 2006.
(60) Provisional application No. 60/862,928, filed on Oct. 25, 2006.
(60) Provisional application No. 60/888,908, filed on Feb. 8, 2007.
(60) Provisional application No. 60/890,306, filed on Feb. 16, 2007.
(60) Provisional application No. 60/917,297, filed on May 10, 2007.

(51) Int. Cl. C01B 21/06; C01B 31/30; C01C 3/08; C23C 14/32

(52) U.S. Cl. 423/371; 204/164; 423/409; 423/439; 204/192.38

(57) ABSTRACT

The present invention allows the relatively easy production of binary and ternary compounds of metals, including noble metals. Embodiments of the invention allow, for the first time, the production of novel compositions of metal compounds, such as thick, stress-free single-phase binary and ternary compositions of metals, and porous compositions of such compounds. As such, the present invention allows for the production of metal compounds and/or compositions of matter thereof that have not before been possible, thereby providing for important new materials that find use in a multitude of different applications, including medical device and non-medical device applications.

### CROSS REFERENCE TO RELATED APPLICATIONS

This application claims priority to U.S. Provisional Application Ser. No. 60/805,464 titled “Implantable Medical Devices Comprising Cathodic Arc Produced Structures” and filed on Jun. 21, 2006; U.S. Provisional Application Ser. No. 60/805,578 titled “Cathodic Arc Deposition Hermetically Sealed Implantable Structures” and filed on Jun. 22, 2006; U.S. Provisional Application Ser. No. 60/805,576 titled “Implantable Medical Devices Comprising Cathodic Arc Produced Structures” and filed on Jun. 22, 2006; U.S. Provisional Application Ser. No. 60/805,581 titled “Noble Metal Compounds Produced by Cathodic Arc Deposition” and filed on Jun. 22, 2006; U.S. Provisional Application Ser. No. 60/862,928 titled “Medical Devices Comprising Cathodic Arc Produced Microstrip Antennas” and filed on Oct. 25, 2006; U.S. Provisional Application Ser. No. 60/888,908 titled “Metal Binary And Ternary Compounds Produced by Cathodic Arc Deposition” and filed on Feb. 8, 2007; U.S. Provisional Application Ser. No. 60/890,306 titled “Metal Binary And Ternary Compounds Produced by Cathodic Arc Deposition” and filed on Feb. 16, 2007; and U.S. Provisional Application Ser. No. 60/917,297 titled “Mental Binary And Ternary Compounds Produced by Cathodic Arc Deposition” and filed on May 10, 2007; the disclosures of which applications are herein incorporated by reference.

### INTRODUCTION

Noble metals are metals that are resistant to corrosion or oxidation, unlike most base metals. They tend to be precious metals, often due to perceived rarity. Examples include gold, silver, tantalum, platinum, and palladium. Of great interest is the production of noble metal compounds of nitrogen and/or carbon, e.g., noble metal nitrides, carbides, carbonitrides, etc., as such compounds have the potential for novel and useful properties that would make them suitable for use in a variety of applications, including medical device applications.

To date, only limited reports exist of binary and ternary compounds of noble metals. For example, Gergoryanz et. al., “Synthesis and characterization of a binary noble metal nitride,” reports the production of platinum nitride using high pressure, high temperature conditions. See also Yu and Zhang, “Platinum nitride with fluorite structure,” eScholarships Repository, University of California (2005); and Crowhurst et al., “Synthesis and characterization of the nitrides of platinum and iridium,” Science (Mar. 3, 2006) Vol. 311:1275-1278. Likewise, the production of gold nitrides has recently been reported. See e.g., Siller et al., “Gold film with gold nitride—a conductor but harder than gold,” Applied Physics Letters 86 (2005) 221912. Krishnamurthy et al., “Nitrogen ion irradiation of Au(110): photoemission spectroscopy and possible crystal structures of gold nitride.” Physical. Review B 70 (2004) 045414; and Siller et al., “Nitrogen ion irradiation of Au(110): formation of gold nitride,” Surface Science 513 (2002) 78. See also WO 2005/121395 titled “Methods of Making Gold Nitride.”

While the above limited reports of the production of noble metal nitrides, e.g., platinum and gold nitrides, exist, the production methods employed in these reports are not optimal.

As such, there continues to be a need in the art to identify new fabrication techniques for producing binary and ternary compounds of noble metals. Of particular, interest would be the development of efficient, easy to use protocols that can produce nitrides, carbides and carbonitrides of noble metals, e.g., gold and platinum. The present invention satisfies this, and other, needs.

### SUMMARY

The present invention allows the relatively easy production of binary and ternary compounds of metals, including noble metals. Embodiments of the invention allow, for the first time, the production of novel compositions of metal compounds, such as thick, stress-free single-phase binary and ternary compositions of metals, and porous compositions of such compounds. As such, the present invention allows for the production of metal compounds and/or compositions of matter thereof that have not before been possible, thereby providing for important new materials that find use in a multitude of different applications, including medical device and non-medical device applications.

### BRIEF DESCRIPTION OF THE FIGURES

FIG. 1 provides a schematic depiction of a cathodic arc plasma source according to an embodiment of the invention.

FIGS. 2A and 2B provide views of different filtering elements that may be employed in embodiments of the methods.

FIG. 3 is a schematic diagram of a cathodic arc ion deposition apparatus according to an embodiment of the present invention.

FIG. 4. In FIG. 4, panel (A) is TEM image of cathodic plasma synthesized AuNₓ film; panel (B) provides the Au 4f peak profiles of AuCₓN_{y}, AuNₓ and AuC, films; panel (C) provides the N is peak profiles of AuCₓN_{y} and AuNₓ films; and panel (D) provides the C1s peak profiles of AuCₓN_{y} and AuCₓ films.

FIG. 5. In FIG. 5, panel (A) provides the Pd3 peak profile for PdNₓ film, while panel (B) provides the resolved N is peak profile for PdNₓ film.

FIG. 6A to 6H provides Raman Spectroscopy results for various cathodic arc materials produced and described in the present application.

FIG. 7A provides a diagram showing the different physical states of various compounds produced by the cathodic arc ion deposition protocols described herein; FIG. 7B provides a picture of porous gold nitride produced according to any embodiment of the invention.

### DETAILED DESCRIPTION

The present invention provides an important new tool for producing metal compositions, including noble metal binary and ternary compositions. Using the protocols and systems of the invention, the manufacturer can produce metal compounds and/or compositions of matter thereof that heretofore could not be made. In further describing the subject invention, the methods will be reviewed first in greater detail, followed by a discussion of certain compounds and compositions thereof that can be made by the methods, as well as a review of various systems that can be employed in the subject methods.

### Methods

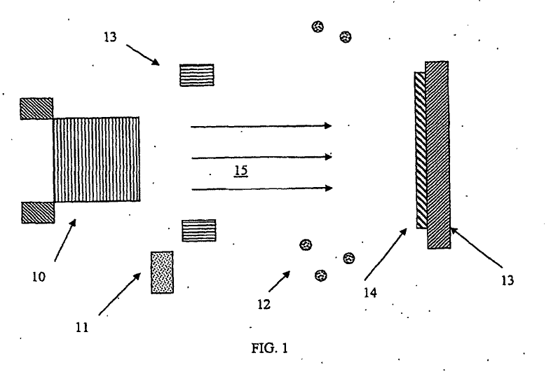

The methods of the invention include contacting a cathodic arc generated metallic ion plasma in the presence of one or more additional elements with a surface of a substrate under conditions sufficient to produce the desired metal binary or ternary composition on the substrate surface. The cathodic arc generated ion plasma of metallic ions may be generated using any convenient protocol. In generating a plasma by cathodic arc protocols, an electrical arc of sufficient power is produced between a cathode and one or more anodes so that an ion plasma of cathode material ions is produced. The resultant plasma is directed to a surface of a substrate in a manner such that the ions contact the substrate surface and produce a structure on the substrate surface made up of the desired metal binary or ternary composition. See e.g., FIG. 1.

The plasma generated in practicing the methods is sufficiently energetic to result in production of the desired compound. In certain embodiments, the plasma is highly energetic, ranging from 10 to 150 eV. The plasma is sufficiently ionized to produce the desired product, where ionization may be 90% or more, such as 95% or more, including 99% or more, e.g., fully (100%) ionized.

Any convenient protocol for producing a structure via cathodic arc deposition may be employed, where protocols known in the art which may be adapted for use in the present invention include, but are not limited to those described in U.S. Pat. Nos. 6,929,727; 6,821,399; 6,770,178; 6,702,931; 6,663,755; 6,645,354; 6,608,432; 6,602,390; 6,548,817; 6,465,793; 6,465,780; 6,436,254; 6,409,898; 6,331,332; 6,319,369; 6,261,421; 6,224,726; 6,036,828; 6,031,239; 6,027,619; 6,026,763; 6,009,829; 5,972,185; 5,932,078; 5,902,462; 5,895,559; 5,518,597; 5,468,363; 5,401,543; 5,317,235; 5,282,944; 5,279,723; 5,269,896; 5,126,030; 4,936,960; and Published U.S. Application Nos.: 20050249983; 20050189218; 20050181238; 20040168637; 20040103845; 20040055538; 20040026242; 20030209424; 20020144893; 20020140334 and 20020139662; the disclosures of which are herein incorporated by reference.

In certain embodiments a system as shown in FIG. 1 is employed. In FIG. 1, the depicted cathodic arc deposition system includes a metal cathode 10 present in a vacuum chamber and a gas inlet 11 that is employed to generate the desired plasma. In such systems, a sufficiently energized plasma is produced by applying high current to the cathode relative to the vacuum chamber walls. Operating current values of interest are 1 Amp or higher, such as 5 Amps or higher, and range in certain embodiments from 1 to 500 Amps, such as from 5 Amps to 100 Amps. During a given fabrication process, the operating current may be continuous or pulsed, where in pulsed protocols the operating current is turned on for a period of time and then off for a period of time, with the cycle repeating a desired number of times. In pulsed embodiments, periods may range in length from 0.1 to 1000 sec, such as 10 to 100 sec.

A gaseous source or sources of additional elements, e.g., N, C, etc., as developed in greater detail below, is introduced into the chamber via inlet 11 during plasma generation and also ionized, when desired. The gas is introduced under pressure where desired, with pressures of interest ranging from 0.01 to 760 torr, such as 0.1 to 100 torr, where the pressure is chosen in part depending on desired nature of the composition of matter to be produced, e.g., solid layer, porous layer, etc.

The total deposition time of a given protocol may also vary. In certain embodiments, the deposition time ranges from about 1 sec to about 10 hours, such as from about 1 min to about 120 min and including from about 5 min to about 60 min.

The composition of the deposited structure may be selected based on the choice of cathode material and atmosphere of plasma generation and/or deposition. As such, a particular cathode material and atmosphere of plasma generation and/or deposition are selected to produce a metallic layer of desired composition, e.g., one made up of a binary or ternary compound of a noble metal.

The cathode is made up of a metal of interest, where metals of interest include, but are not limited to: aluminum (at), gold (au), silver (ag), copper (cu), iridium (ir), molybdenum (mo), niobium (nb), osmium (os), palladium (pd), platinum (pt), rhenium (re), rhodium (rh), ruthenium (ru), tantalum (ta), titanium (ti), tungsten (w) and the like in certain embodiments, the cathode is made up of a noble metal, where noble metals of interest include, but are not limited to: gold (au), silver (ag), osmium (os), palladium (pd), platinum (pt), rhodium (rh), iridium (ir) and the like.

In certain embodiments, cathode is made up of a platinum group metal platinum group metals of interest are: platinum (pt), iridium (ir), palladium (pd), rhodium (rh), osmium (os) and ruthenium (ru) in certain embodiments, the metal is a gold group metal gold group metals of interest are: gold (au), silver (ag) and copper (cu) also of interest are transition metal, including refractory metals refractory metals that may make up the cathode include: rhenium (re), tungsten (w), molybdenum (mo), niobium (nb), and tantalum (ta).

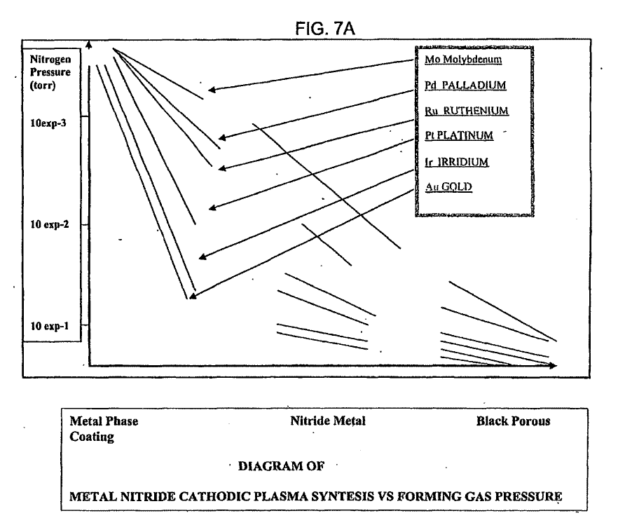

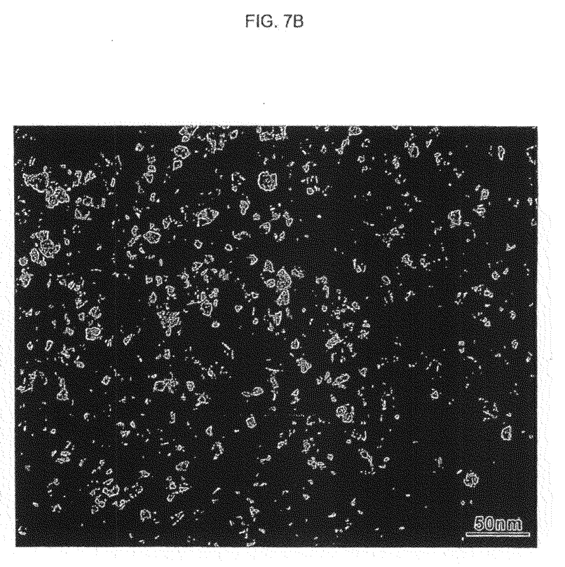

The plasma may be produced in a vacuum in those embodiments where the deposited structure is to have the same composition as the cathode. In yet other embodiments where the deposited structure is to be compound of a metal with another element, such as but not limited to: oxygen; carbon; nitrogen; inert gases such as helium, xenon, radon; etc., the plasma may be produced in an atmosphere of the other element, e.g., an oxygen containing atmosphere, a nitrogen containing atmosphere, a carbon containing atmosphere, etc. The partial pressure of the second (or third) element(s) in the atmosphere is selected based on the desired product composition, including its physical state. In certain embodiments, the partial pressure of the atmospheric element(s) is at 25 about millitorr or higher, such as about 35 millitorr or higher. By adjusting the pressure, the physical state of the production composition can be controlled. See e.g., FIG. 7. The gaseous element may be provided in the chamber by introducing any convenient reactive gas source of the element. Reactive gas sources of nitrogen include N₂, NH₄, NO, NO₂, etc. Reactive gas sources of carbon include C₂H₆, C₃H₉, CH₄, C₂H₂, etc. For production of ternary compounds, two or more different reactive gases are introduced into the chamber, e.g., N₂ and C₂H₆, etc.

In certain embodiments, a gradient of a second element in the cathode material is produced in the deposited structure, e.g., by modifying the atmosphere while the plasma is being generated, such that the amount of the second element in the atmosphere is changed, e.g., increased or decreased, while deposition is occurring.

In certain embodiments, the plasma (also referred to herein as the “ion beam”) that is contacted with the substrate surface is unfiltered, such that the ion beam includes macroparticles 12 of the cathode material. In yet other embodiments, the ion beam may be filtered such that the beam that is contacted with the substrate surface is substantially if not completely free of macroparticles. Any convenient filtration protocol may be employed, such as those described in U.S. Pat. Nos. 6,663,755; 6,031,239; 6,027,619; 5,902,462; 5,317,235 and 5,279,723 and published U.S. Application Nos. 20050249983; 20050181238; 20040168637; 20040103845 and 20020007796; the disclosures of which are herein incorporated by reference.

The substrate 13 employed in the subject methods may vary widely, ranging from silicon, Si/SiO₂, glass, metals, plastics, ceramics, etc.

In addition to producing novel compounds, the subject methods are also suitable for fabrication of compositions of matter of novel compounds described herein as well as previously known compounds that may have been fabricated using other methods, where the compositions of matter have not been heretofore possible to make. The phrase “composition of matter” means the form of the compound material that is produced, and refers to a characteristic of the form of the material, e.g., solid, slab, porous layer, uniform layer, etc.

In certain embodiments, the compositions of matter are made up of compounds that may have been made previously in the art by other protocols, but not in the masses obtained using cathodic arc deposition processes described herein. In such instances, the mass of the material produced according to methods of the present invention may be 2-fold or more than previously obtainable, such as 5-fold or more than previously obtainable. In certain embodiments, the volume of the product may be a 6 inch radius by 1 micron thick volume or more, such as a 6 inch radius by 10 micron thick volume or more, including a 6 inch radius by 100 micron thick volume or more.

In certain embodiments, compositions of matter that are produced using the subject methods are layers of material present on a solid support. As such, the method is one that produces a metallic layer on a surface of the substrate that has a thickness of about 1 μm or greater, such as a thickness of about 25 μm or greater, including a thickness of about 50 μm or greater, where the thickness may be as great at about 75, 85, 95 or 100 μm or greater. The layers may cover an area that varies depending on the particular protocol, where ranges of interest include from 0.01 to 10,000 cm², such as 10 to 100 cm². These deposited layers may be employed as starting materials in fabrication of a variety of different components of devices for use in a variety of different applications, e.g., electronics, medical devices, etc.

In certain embodiments, the cathodic arc deposition protocol employed is one that produces a thick, stress-free metallic structure on a surface of a substrate, e.g., as described above. As such, the method is one that produces a defect free metallic layer on a surface of the substrate that has a thickness of about 1 μm or greater, such as a thickness of about 25 μm or greater, including a thickness of about 50 μm or greater, where the thickness may be as great at about 75, 85, 95 or 100 μm or greater.

In certain embodiments, contact of the plasma and the substrate surface in the subject methods occurs in a manner such that compressive and tensile forces experienced by deposited metal structure substantially cancel each other out so that the deposited metal structure is stress-free. In these embodiments, various parameters of the deposition process, including distance between the substrate and the cathode, temperature of the substrate and the power employed to produce the plasma are selected so that the product metallic layer is stress-free. In these embodiments, the distance between the substrate and the cathode may range from about 1 mm to about 0.5 m. The power employed to generate the plasma may range from about 1 watt to about 1 Kilowatt or more, e.g., about 5 Kilowatts or more.

In certain embodiments, the plasma is contacted with the substrate surface in a direction that is substantially orthogonal to the plane of the substrate' surface on which the structures are to be produced. By “substantially orthogonal” is meant that the angle of the ion beam flow as it contacts the plane of the substrate ±15°, such as ±10°, including ±5° of orthogonal, including orthogonal, such that in certain embodiments the ion beam flow is normal to the plane of the substrate surface.

In yet other embodiments, deposition conditions (e.g., gas makeup, power) may be selected which yield a porous coating. For example, the pressure of the reactive gases may be chosen to provide for a desired porosity in the final product, e.g., as illustrated in FIG. 7A and exemplified by the picture of porous gold nitride provided in FIG. 7B.

### Compounds and Compositions of Metal Binary and Ternary Compounds

The invention also provides novel metal binary and ternary compounds. The metal binary and ternary compounds are, in certain embodiments, compounds of a metal that is aluminum (al), gold (au), silver (ag), copper (cu), iridium (ir), molybdenum (mo), niobium (nb), osmium (os), palladium (pd), platinum (pt), rhenium (re), rhodium (rh), ruthenium (ru), tantalum (ta), titanium (ti), tungsten (w) and the like. In certain embodiments, the metal is a noble metal, where noble metals of interest include, but are not limited to: gold (au), silver (ag), osmium (os), palladium (pd), platinum (pt), rhodium (rh), iridium (ir) and the like. In certain embodiments, the metal is a platinum group metal. Platinum group metals of interest are: platinum (pt), iridium (ir), palladium (pd), rhodium (rh), osmium (os) and ruthenium (ru). In certain embodiments, the metal is a gold group metal gold group metals of interest are: gold (au), silver (ag) and copper (cu) also of interest are transition metals, including refractory metals refractory metals include: rhenium (re), tungsten (w), molybdenum (mo), niobium (nb), and tantalum (ta).

The metal binary and ternary compounds of the invention include one or more additional elements, such as one or two additional elements. Additional elements of interest include, but are not limited to: oxygen, nitrogen, carbon, chlorine, fluorine, an inert gas (e.g., helium, xenon, radon), etc. Accordingly, of interest are metal nitrides and carbides, as well as metal carbonitrides, etc. Specific compounds of interest include, but are not limited to: nitrides, such as platinum nitride, gold nitride, ruthenium nitride, palladium nitride, iridium nitride, molybdenum nitride, copper nitride, silver nitride, rhenium nitride, etc.; carbides, such as platinum carbide, gold carbide, rhuthenium carbide, palladium carbide, silver carbide, osmium carbide, etc.; carbonitrides, such as gold carbonitride, platinum carbonitride, etc; and the like.

Compounds of the invention may exhibit a variety of different properties of interest. Semiconductor compounds of the invention include platinum nitride, ruthenium nitride, and the like. Superconductor compounds of the invention include gold nitride, rhenium nitride, copper nitride, and the like. Compounds that can make up hard materials include gold nitride, gold carbide, platinum nitride, etc.

Embodiments of the invention include compositions produced by cathodic arc deposition protocols, e.g., via the protocols described above. As reviewed above, the protocols employed may produce layers of metal binary and ternary compounds of dimension heretofore unobtainable.

In certain embodiments, the cathodic arc deposition protocol employed is one that produces a thick, stress-free metallic structure on a surface of a substrate, e.g., as described above. As such, the method is one that produces a defect-free metallic layer on a surface of the substrate that has a thickness of about 1 μm or greater, such as a thickness of about 25 μm or greater, including a thickness of about 50 μm or greater, where the thickness may be as great at about 75, 85, 95 or 100 μm or greater. In addition, the compositions are, in certain embodiments, single phase compositions.

The compounds and compositions of matter of the invention find use in a variety of different applications, from medical applications (e.g., as components in medical devices) to industrial applications, e.g., in electronics circuitry, etc. In certain embodiments, the metal compounds, e.g., nitrides, carbonitrides, etc., as described above, are present in an implantable medical device. By implantable medical device is meant a device that is configured to be positioned on or in a living body, where in certain embodiments the implantable medical device is configured to be implanted in a living body. Embodiments of the implantable devices are configured to maintain functionality when present in a physiological environment, including a high salt, high humidity environment found inside of a body, for 2 or more days, such as about 1 week or longer, about 4 weeks or longer, about 6 months or longer, about 1 year or longer, e.g., about 5 years or longer. In certain embodiments, the implantable devices are configured to maintain functionality when implanted at a physiological site for a period ranging from about 1 to about 80 years or longer, such as from about 5 to about 70 years or longer, and including for a period ranging from about 10 to about 50 years or longer. The dimensions of the implantable medical devices of the invention may vary. However, because the implantable medical devices are implantable, the dimensions of certain embodiments of the devices are not so big such that the device cannot be positioned in an adult human. The function of the implantable medical devices of the invention may vary widely, including but not limited to: cardiac devices, drug delivery devices, analyte detection devices, nerve stimulation devices, etc. Illustrative embodiments of various types of implantable medical devices of the invention are reviewed in greater detail below.

### Utility

The compounds and composition thereof of the invention find use in a variety of different and wide ranging applications, including industrial applications, medical applications, etc. For example, platinum nitride produced by embodiments of the invention is a semiconductor and can be hard or porous, making it suitable for use in, e.g., medical electrodes, integrated circuits, catalysts, etc. Copper nitride produced by embodiments of the invention is a superconductor finding use in MRI machines, bullet trains, etc. Gold nitride produced by embodiments of the invention may exhibit one or more of high hardness, extreme durability, superconductor and photo luminescent, thereby finding use in x-ray & e-beam lithography, medical electrodes, integrated circuits, catalysts etc. Rhenium nitride produced by embodiments of the invention is a superconductor finding use in MRI machines, bullet trains, etc. Gold carbide produced by embodiments of the invention may exhibit one or more of hardness, porosity, or photo luminescent, thereby finding use in x-ray & e-beam lithography, nanoparticle production, etc. Ruthenium nitride produced by embodiments of the invention is a semiconductor, making it suitable for use in, e.g., integrated circuits, etc.

Medical applications in which the compounds and compositions of the invention find use are further described in U.S. Provisional Application Ser. No. 60/805,464 titled “Implantable Medical Devices Comprising. Cathodic Arc Produced Structures” and filed on Jun. 21, 2006; U.S. Provisional Application Ser. No. 60/805,578 titled “Cathodic Arc Deposition Hermetically Sealed Implantable Structures” and filed on Jun. 22, 2006; U.S. Provisional Application Ser. No. 60/805,576 titled “Implantable Medical Devices Comprising Cathodic Arc Produced Structures” and filed on Jun. 22, 2006; U.S. Provisional Application Ser. No. 60/805,581 titled “Noble Metal Compounds Produced by Cathodic Arc Deposition” and filed on Jun. 22, 2006; U.S. Provisional Application Ser. No. 60/862,928 titled “Medical Devices Comprising Cathodic Arc Produced Microstrip Antennas” and filed on Oct. 25, 2006; U.S. Provisional Application Ser. No. 60/888,908 titled “Metal Binary And Ternary Compounds Produced by Cathodic Arc Deposition” and filed on Feb. 8, 2007; U.S. Provisional Application Ser. No. 60/890,306 titled “Metal Binary And Ternary Compounds Produced by Cathodic Arc Deposition” and filed on Feb. 16, 2007; and U.S. Provisional Application Ser. No. 60/917,297 titled “Mental Binary And Ternary Compounds Produced by Cathodic Arc Deposition” and filed on May 10, 200; the disclosures of which applications are herein incorporated by reference.

### Cathodic Arc Deposition Systems

Also provided are cathodic arc deposition systems that may be employed in practicing the subject methods to make metal compounds and compositions of the invention, e.g., metal binary and ternary compounds, e.g., noble metal nitrides, noble metal carbides and carbonitrides, etc. Embodiments of the subject systems include a cathodic arc plasma source and a substrate mount. The cathodic arc plasma source (i.e., plasma generator) may vary, but in certain embodiments includes a cathode, one or more anodes and a power source between the cathode and anode(s) for producing an electrical arc sufficient to produce, ionized cathode material from the cathode during plasma generation. The plasma generator may generate a DC or pulsing plasma beam, including positively charged ions from a cathode target.

The substrate mount is configured for holding a substrate on which a structure is to be deposited. In certain embodiments, the substrate mount is one that includes a temperature modulator for controlling the temperature of a substrate present on the mount, e.g., for increasing or decreasing the temperature of a substrate on the mount to a desired value. Any convenient temperature modulator may be operatively connected to the mount, such as a cooling element, heating element etc. In certain embodiments, a temperature sensor may be present for determining the temperature of a substrate present on the mount.

In certain embodiments, the system is configured so that the distance between the substrate mount and the cathode may be adjusted. In other words, the system is configured such that the substrate mount and cathode may be moved relative to each other. In certain embodiments, the system is configured so that the substrate mount can be moved relative to the cathode so that the distance between the two can be increased or decreased as desired. In certain embodiments, the system is configured so that the cathode can be moved relative to the substrate mount so that the distance between the two can be increased or decreased as desired.

The cathode generation element and substrate are, in certain embodiments, present in a sealed chamber which provides for the controlled environment, e.g., a vacuum or controlled atmosphere, where the two components of the system may be present in the same chamber or different chambers connected to each other by an ion conveyance structure which provides for movement of the ions from the cathode to the substrate.

One or more gas inlet ports may be provided in the chamber, e.g., for introducing a reactive gas(es) into the chamber during deposition, where the reactive gas may be introduced under pressure.

In certain embodiments, the system further includes a filter component which serves to filter macroparticles from the produced plasma so that a substantially if not completely macro-particle free ion beam contacts the substrate. Any convenient filtering component may be present, where filtering components of interest include, but are not limited to: those described in U.S. Pat. Nos. 6,663,755; 6,031,239; 6,027,619; 5,902,462; 5,317,235 and 5,279,723 and published U.S. Application Nos. 20050249983; 20050181238; 20040168637; 20040103845 and 20020007796; the disclosures of which are herein incorporated by reference. In certain embodiments, the filter element has two bends such that there is no line of sight and no single bounce path through the filter between the source and the substrate. In certain embodiments, the system further includes a beam steering arrangement, which steers the plasma beam through a filter and onto the substrate.

In certain embodiments, the system includes an ion beam modulator, e.g., a beam biasing arrangement for applying a pulsed, amplitude modulated electrical bias to a filtered plasma beam. In these embodiments, the biasing arrangement comprises a processing device and a pulse generator module, the pulse generator module generating the pulsed, amplitude modulated electrical bias under the control of the processing device in which the pulse generator module includes a programmable logic device, a power supply and a switching circuit, the switching circuit being controlled by the programmable logic device and an output of the power supply being coupled to the substrate via the switching circuit, wherein the programmable logic device controls the operation of both the power supply and the switching circuit.

In certain embodiments, the system further includes an element for biasing the substrate. In certain of these embodiments, the biasing operates both to dissipate electrostatic charge accruing on the substrate due to the deposition of positive ions and to ensure that the energy of incident ions falls in a predetermined energy range.

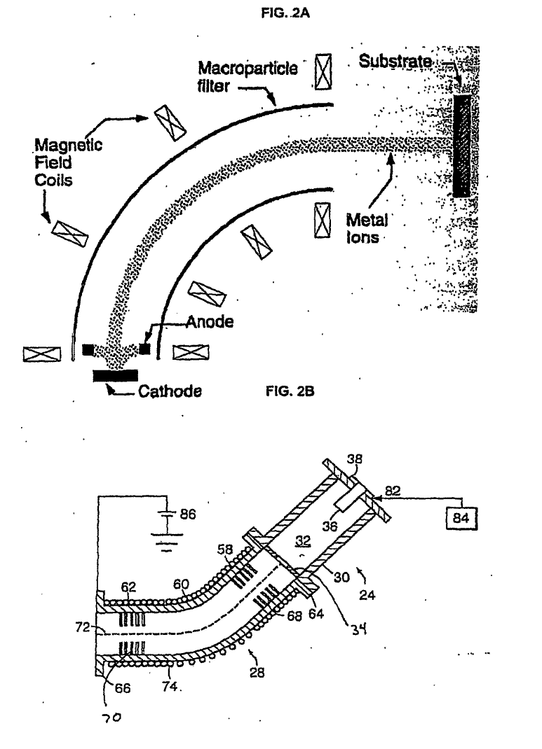

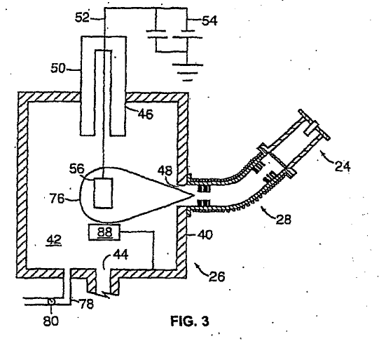

Referring to FIGS. 2B and 3, an embodiment of the present invention has been schematically illustrated utilizing a curved magnetic field connecting an ion source to the substrate to be coated. A cathodic arc source, generally indicated by 24, is connected to a vacuum deposition chamber, generally indicated by 26, by a curved or bent magnetic duct assembly 28. The source 24 comprises a housing 30 forming a chamber 32 therein. At opposite ends of chamber 32 are positioned an anode assembly 34 and a cathode assembly 36. Both assemblies are of known construction and include cooling means (not shown) and power connections 82. A power control 84 permits adjustment of the potential applied to cathode assembly 36. The cathode assembly 36 contains a cathode formed from the noble metal to be deposited. As such, the cathode is a noble metal cathode, such as platinum, gold, etc. An arc starter 38 may be provided. In certain embodiments, anode assembly 34 is a metal ring. The normal seals and other conventional structural features of an arc source have not been shown for sake of simplicity of the drawings.

The vacuum deposition chamber 26 is a closed housing 40 defining a chamber 42, vacuum port 44, bias port 46, one or more plasma ports 48 (one is shown, for clarity), and gas inlet port 78: The vacuum port 44 is connected to any known means (not shown) for creating a vacuum within chamber 42. The vacuum within the chamber may be in the range of 10⁻⁵ to 10⁻⁷ Torr. The bias port 46 is provided with an insulated feed-through 50 including a conductor 52, one end of which is connected to a voltage source 54 and the other end of which is suspended in chamber 42 to support substrate holder 56. Substrate holder 56 may be fixed or movable. Each plasma port 48 aligns one end of a magnetic duct assembly 28 with the substrate holder 56. The gas inlet port 78 includes valve 80 and permits a vapor or a gas, such as carbon or nitrogen, to be introduced into chamber 42. Heater 88 is positioned within vacuum position chamber 26 to permit the heating of a substrate on substrate holder 56.

The magnetic duct assembly 28 comprises a straight cylindrical entrance section 58, an intermediate arcuate section 60, and a straight cylindrical exit section 62. In certain embodiments, magnetic duct assembly 28 provides an approximately 45 degree bend between entrance section 58 and exit section 62 and, with power supply 86, is positively biased relative to the cathode in the range of 5 to 500 volts. The positive bias produces an electric field within the duct assembly, which helps to increase the directionality of the plasma generated in the cathodic arc source. In certain embodiments, the potential applied to the duct assembly is adjustable. Sections 58 and 62 have mounting flanges 64, 66, respectively.

The angle in duct assembly 28 prevents line-of-sight between the arc and the substrate, and serves as a macro-particle filter. First and second baffles 68, 70 of nonmagnetic material, such as stainless steel, are fixed in the respective entrance and exit sections 58, 62 to define an axial passage, noted by the broken line 72. In certain embodiments, there are between 5 and 10 annular discs in each baffle 68 and 70, with the discs spaced approximately 0.5 to 2 cm apart. The particular number, spacing and specific location of the discs and baffles 68, 70 depends, for example, on the single-bounce pattern of macro-particles from the arc substrate or cathode. In certain embodiments, the baffles are configured so as to prevent macro-particles from reaching vacuum chamber 42 and the parts to be coated. The annular discs of baffles 68, 70 may be aligned axial apertures in the range of 3-10 cm in diameter. Helical coil 74, which is wound around the outside of duct assembly 28, is connected to a power source (not shown). Coil 74 produces an axial magnetic field through duct assembly 28 to direct the plasma generated in the cathodic arc source. The magnetic field through duct assembly 28 may be adjustable (e.g., by controlling the power applied to coil 74), with an axial magnetic field strength from approximately 500 Gauss to 5 KiloGauss.

FIG. 2A provides a view of another embodiment of a duct, which is a 90 degree duct as opposed to the 45 degree duct shown in FIG. 2B.

In certain embodiments, the substrate bias is controlled relative to the source during the deposition. Making the substrate more negative has the effect of increasing beam energy and directionality. As the metal is deposited, the substrate can be biased more positive, thereby decreasing the beam energy and making it less directional.

If gases or vapors are introduced through gas inlet 78 into the vacuum deposition chamber along with the ion beam; the deposited material can be changed. For example, when depositing titanium to form deep contacts, nitrogen can be introduced into the chamber in order to form a titanium nitride deposit.

Heater 88 may be used to heat a substrate on substrate holder 56 during or after deposition of the metal ions.

The following examples are offered by way of illustration and not by way of limitation.

### EXPERIMENTAL

### I. Plasma Synthesis of Platinum- and Gold-Group Carbide, Nitride and Carbonitride Compounds

### A. Introduction

The arc plasma synthesis of the nitrides, carbides and carbonitrides of the metal thin films of platinum, indium, palladium, ruthenium and gold is reported. Most of these compounds, particularly the carbides and carbonitrides, are reported for the first time. Thin films of the compounds were confirmed with Raman spectroscopy and x-ray photoelectron spectroscopy (XPS).

### B. Materials/Methods

The synthesis of metal nitride, carbide and carbonitrides was accomplished using reactive cathodic arc deposition (A. Anders, G. Yushkov, J. Appl. Phys. 91, 4824, (2002)). Pure metal cathodes were placed in a vacuum chamber. A cathodic arc was established by applying a high current power supply to the cathode relative to the vacuum chamber walls. This created an explosive plasma at non-stationary spots on the cathode surface. The resulting plasma was highly energetic (10 to 150 eV) and fully ionized with multiply ion charge states. When a gas was added to the chamber the gas molecules were also ionized. The pressures of nitrogen, acetylene, or both were adjusted empirically in the range of 0.01 to 0.1 Torr to achieve a uniform thin film of the target compound. Specifically, 1 micrometer of the corresponding metal was first cathodic arc deposited on standard silicon wafer in vacuum of 10⁻⁵-10⁻⁶ Torr. Next, reactive gas was introduced into the chamber and 20 Volts cathode working voltage was pulsed on for 60 second intervals followed by 60 second cooling periods. The cumulative deposition timed averaged 30 minutes.

XPS spectra were taken with a PHI Quantum 2000 spectrometer with a monochromated Al K_{α}1486 eV source, calibrated to the C1s 284.8 eV line. The usual pre-XPS argon cleaning procedures were not performed so as to eliminate the chance of surface modification (particularly of these previously unknown materials).

### C. Results

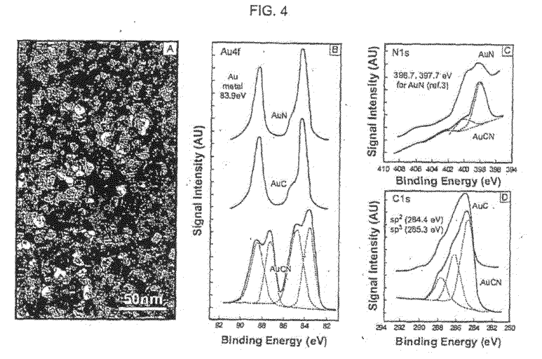

The resulting films (1 to 3 micrometers thick) deposited on 4″ substrates were characterized with transmission electron microscopy (TEM), Raman spectroscopy and XPS. TEM revealed stable nano-crystalline structures (FIG. 4, panel A). The broadening of the Raman peaks varied to a large degree depending on the crystallinity and electrical conductivity of each sample.

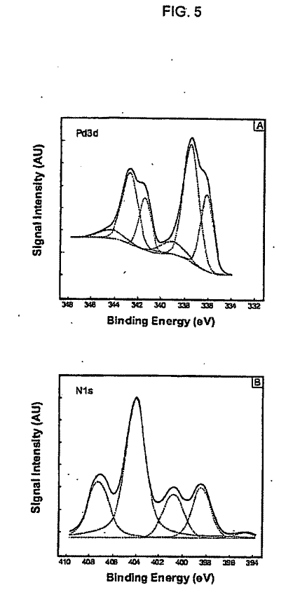

The XPS scans of PtNₓ, IrNₓ, and AuₓN show N1s peaks in a good agreement with published data. For AuCₓN_{y}, AuₓN and AuCₓ the Au4f (FIG. 4, panel B), N1s (FIG. 4, panel C) and C1s (FIG. 4, panel D) lines show broadened or split peaks that have been resolved using a non-linear least squares (NLLS) fitting algorithm. We attribute the shift of 4f₇₁₂, C1s, and N1s peaks to the formation of Me-C, Me-N, C-Me-N covalent bonds. The multiple XPS peaks may also indicate the formation of more than one compound phase. Interestingly, PdNₓ shows multiple Pd3d and four resolved N1s peaks centered from 398.8 eV to 406.8 eV (FIG. 5, panel A).

The Ir 4f₇₁₂ binding energy lines of Ir compounds were observed to be shifted as follows: IrCₓN_{y}, 62.1 eV; IrCₓ, 63.9 eV; and IrNₓ, 63 eV compared with 60.8 eV for Ir metal. The Pt4f_{7/2} line for PtCₓN_{y} occurs at 73 eV, PtCₓ at 72.9 eV, and PtNₓ at 71.2 eV, compared to 70.8 eV for Pt. The Ru3d_{5/2} lines for RuCₓN_{y}, RuCₓ and RuNₓ occur at 281.6, 281.1, and 283.3 eV respectively compared with 280 eV for Ru. The Pd3d lines are: 337.2 for PdCₓN_{y} and 336.7 eV for PdCₓ, versus 335.1 eV for Pd metal. FIG. 5, panel E shows the XPS spectra for the PdNₓ film. The P3d profile comprises two lines centered at 336 and 337:5 eV. There is probably a third smaller intensity line located at 339 eV. The N1S is represented by broad peak which has been resolved into 4 components at 398.8, 400.1, 403.9 and 406.8 eV with a FWHM of 1.75 eV each. The last two peaks represent bonds with binding energies noticeably higher then reported for N—O (402.5 3 eV), N—C (398 to 400.5 eV) or N—N (400.5 to 401.3 eV).

### D. Discussion

Noble metals rarely form compounds. Here we report the synthesis and characterization of the nitrides, carbides and carbonitrides of transition metals from the platinum and gold groups: platinum, iridium, palladium, ruthenium and gold. The majority of these compounds have not been previously described in the literature.

### II. Synthesis of Noble Metal Compounds

Various binary and ternary compounds were produced via cathodic arc according to the parameters provided in Table 1, below.

TABLE 1

| | Nitride | | | Carbide | | | Carbonitride | | |
|---|---|---|---|---|---|---|---|---|---|
| | N₂ | Cathode | | C₂H₂ | Cathode | | N₂ + C₂H₂ | Cathode | |
| | Pressure | Power | | Pressure | Power | | Pressure | Power | |
| Pt | 1.5 × 10⁻¹ | 0.5-1.0 | KW | 1-5 × 10⁻² | 0.5-1 | KW | 1 × 10⁻¹ | 1 | KW |
| | Torr | | | Torr | | | Torr | | |
| | brownish | | | dark | | | dark | | |
| | red | | | brown | | | brown | | |
| Au | 1-5 × 10⁻¹ | 0.5-0.8 | KW | 70-80 | 0.5 | KW | 140 Torr | 1 | KW |
| | Torr | | | Torr | | | slightly | | |
| | yellow | | | gold | | | green | | |
| | green | | | brown | | | gold | | |
| Ag | 1 × 10⁻² | 0.5 | KW | | | | | | |
| | Torr | | | | | | | | |
| | dark | | | | | | | | |
| | silver | | | | | | | | |
| Ir | 8 × 10⁻² | 0.5-1.0 | KW | 1 × 10⁻² | 1.0-2.0 | KW | 1 × 10⁻² | 1.0-2.0 | KW |
| | Torr | | | Torr | | | Torr | | |
| | brownish | | | brown | | | brownish | | |
| | blue | | | violet | | | red | | |
| Pd | 5 × 10⁻¹ | 1.0-2.0 | KW | 7 × 10⁻¹ | 1.5-2.0 | KW | | | |
| | Torr | | | Torr | | | | | |
| | brownish | | | brown | | | | | |
| | red | | | | | | | | |

| | | | | | | | |
|---|---|---|---|---|---|---|---|
| Ru | 3 × 10⁻¹ | 1.0 | KW | 1 × 10⁻² | 1.5 | KW | Carbonitride |
| | Torr | | | Torr | | | |
| | brown | | | brown | | | |
| Re | 5 × 10⁻¹ | 0.5-0.8 | KW | 1.5 × 10⁻² | 0.5 | KW | |
| | Torr | | | Torr | | | |
| | brownish | | | brownish | | | |
| | blue | | | green | | | |

In the present work a modified cathodic arc system was employed. As reviewed above, cathodic arc is essentially explosive plasma generated at microscopic, non-stationary spots on the surface of metallic or sufficiently conductive cathodes. The cathodic generated plasma employed in the present work was highly energetic (in range of 10-150 eV), and fully ionized (up to 100%). Synthesis and thin film deposition were performed in a vacuum chamber designed to accommodate water cooled metal cathodes, a filter to minimize the metal macroparticles flux, a gases manifold and water cooled sample holder.

Cathodes that were cast of 99.97% purity noble metals were employed. Thin film deposition was performed on 4 inch Si wafers. The deposition runs were started at 5×10⁻⁵ torr base vacuum and resulted in 2-3 microns thick pure metals layers. Following deposition of the pure metal layers, the reactive gases were introduced into the chamber. The system's gas manifold allowed supplying argon, nitrogen and acetylene gasses. In order to increase the degree of gas ionization and reactivity efficiency the deposition chamber was fitted with two gas inlets. One of the gas inlets was a regular gas inlet located between the cathode and the sample while the second gas inlet was in the form of 0.7 mm aperture centered within the metal cathode. The forming gas was ionized exiting from the aperture, creating a very dense reactive plume Upon increase of, the gas pressure, the synthesis process starts with sudden changes of plasma color and intensity.

The composition and morphology of the resulting product films depended on the gas partial pressure and electrical power applied to generate the arc produced plasma. In the case of the carbonitrides, the nitrogen to acetylene partial pressure was maintained at 2:1. The resultant compound films were 1-3 microns in thickness and varied in color appearance. Since the compounds were formed on metal layers and relatively thick, the exhibited colors possibly reflected inherent compound colors rather then being resulted from the film thickness variations. For example; the PtN film had a brown-reddish color, the IrN film had a bluish-brown color, and the AuN film had a gold-yellow color. Most of carbides had dark grey-brown color while the carbonitrides were dark brown to very dark reddish. The electrical conductivity of the synthesized compounds varied from very dielectric (Ir and Pd based) to good conductors (e.g., AuN and AuC).

To investigate the compounds' thermal stability, the samples were subjected to thermal annealing for 1 hour in an argon atmosphere at 450, 600 and 750° C. It has been found that Ir and Au based compounds were less stable, while Pt and Pd based materials were more stable.

Microphotography revealed in most cases two phase systems. The dark colored phases were un-reacted micron-size metal particles. The brown color presented for most samples could be attributed to the presence in these films the second phase.

Formation of nitrides, carbides and carbonitrides was confirmed for most metals by XPS and Raman techniques. The Auger spectra were employed to characterize several samples atomic composition. The Raman modes showed structurally stable compounds. However, the crystalline structure varied in large degree, from microcrystalline (PtN for example) to highly crystalline (IrN). The different electrical conductivity of the materials also contributed to the broadening of the Raman peaks.

The X-ray Photoelectron Spectroscopy scans were used for both compositional and chemical bonding analysis. It was found that locations of Pt4f7/2, Ir4f7/2 and Au4f7/2 nitride peaks were in very good agreement with published data. Comparison of the 4f7/2 peaks for carbides and carbonitrides with binding energies for the correspondent elemental metals clearly confirms the compound formation. The N1s and C1s peaks shifts relatively N—N, N—C and C—C bonds indicates the existence of nitrides and carbides.

### III. Spectra Analysis of Cathodic Arc Produced Metal Nitrides

### A. Experimental:

The Raman Spectroscopy† measurements were performed using a “LabRam” J-Y Spectrometer with 1800 gr/mm grating. An Ar⁺ ion laser (514.5 nm wavelength) was used as the excitation source. The measurements were performed on backscattering geometry) (180° under an Olympus BX40 microscope (objective X100).

### B. Results and Discussion:

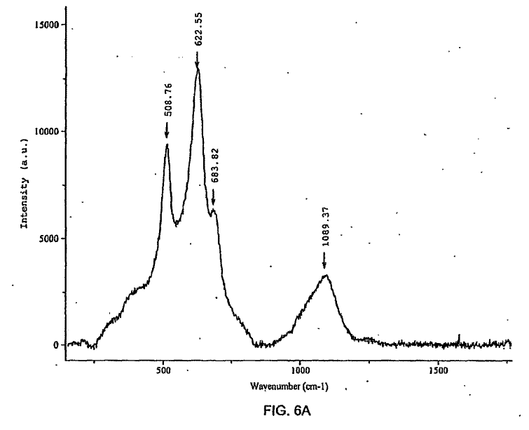

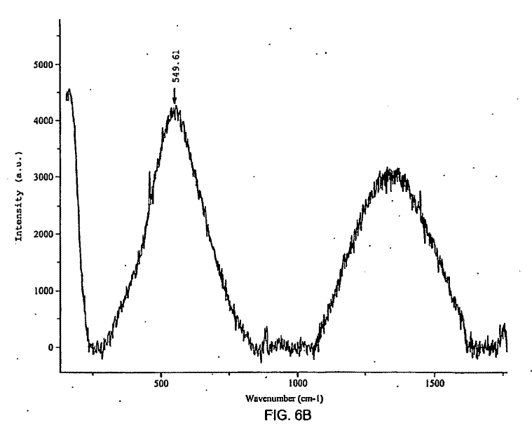

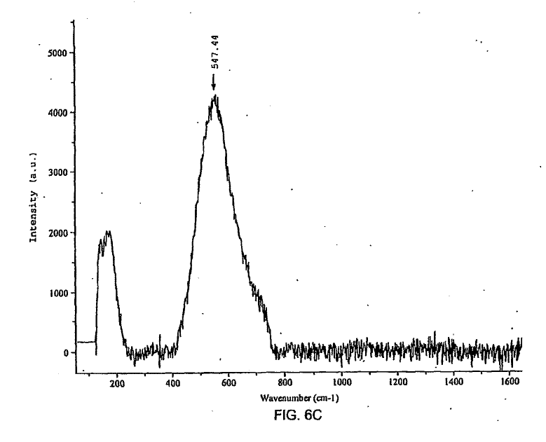

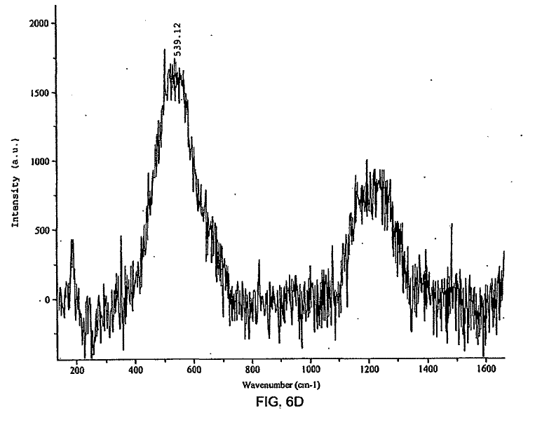

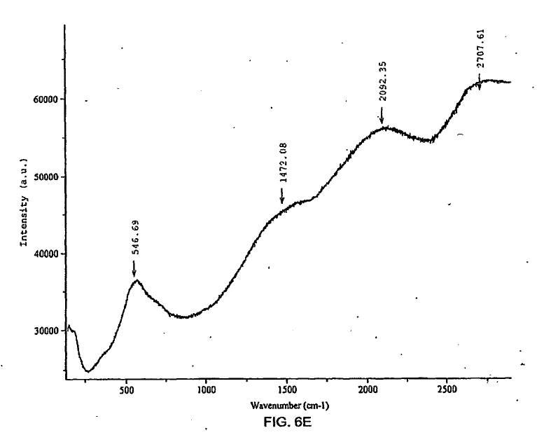

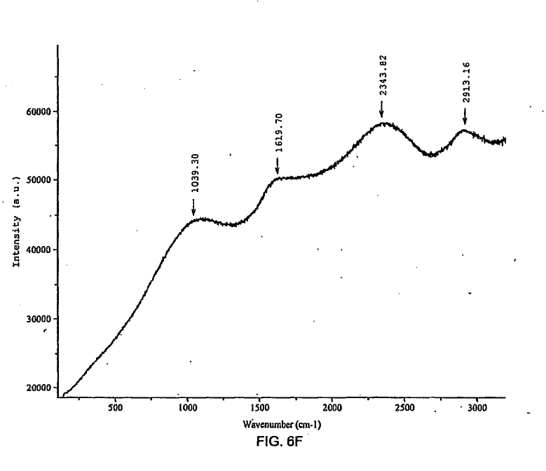

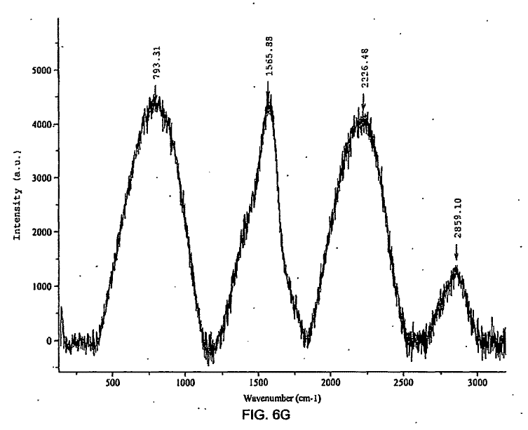

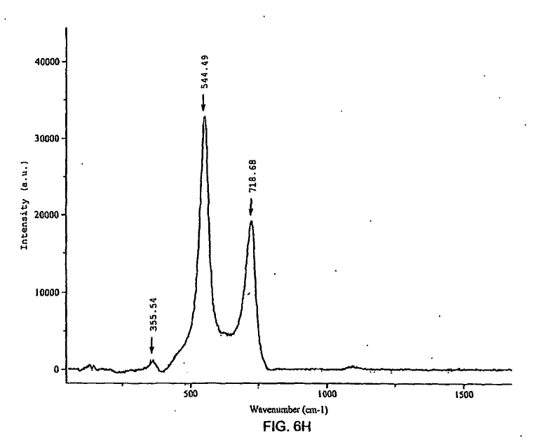

Spectrum 1 (FIG. 6A) was acquired from a sample of RhN. Spectra 2, 3, 4 & 5 (FIGS. 6B to 6E) were acquired from samples of PtN. Spectra 6 & 7 (FIGS. 6F to 6G) were acquired from samples of AuN. Spectrum 8 (FIG. 6H) was acquired from a sample of IrN. All the observed metals had formed nitrides. They were not pure metals, which have no Raman spectra. The Raman spectra of IrN (Spectrum 8, bands at 545 & 718 cm-1) & RhN (Spectrum 1, bands at 509, 622 cm-1) have sharp peaks, (small widths), typical for compounds with relatively larger grain size, while PtN (Spectrum 2, band at ˜549 cm-1) and AuN have broader bands typical of nano-compounds with smaller grain size on the nm range (more amorphous).

IV. Various nitrides were fabricated using the protocols described above while varying the nitrogen pressure. Varying the nitrogen pressure was observed to impact both the chemical make of the resultant product and its physical state, e.g., as a metal layer or porous coating. The results are shown graphically in FIG. 7A. FIG. 7B provides a picture of porous gold nitride produced according to an embodiment of the invention.

It is to be understood that this invention is not limited to particular embodiments described, as such may vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

What is claimed is:

1. A method of producing a metal binary or ternary compound, said method comprising:
producing a cathodic arc generated metallic ion plasma from a metallic cathode and a gas of at least one additional element; and
contacting said metallic ion plasma with a surface of a substrate to produce a metal compound binary or ternary compound.

2. The method according to claim 1, wherein said metallic cathode comprises a metal chosen from: aluminum (al), gold (au), silver (ag), copper (cu), iridium (ir), molybdenum (mo), niobium (nb), osmium (os), palladium (pd), platinum (pt), rhenium (re), rhodium (rh), ruthenium (ru), tantalum (ta), titanium (ti) and tungsten (w).

3. The method according to claim 1, wherein said metal compound is a metal binary compound.

4. The method according to claim 3, wherein metal binary compound is a metal nitride or metal carbide.

5. The method according to claim 1, wherein said metal compound is a metal ternary compound.

6. The method according to claim 5, wherein said metal compound is a carbonitride.

7. The method according to claim 1, wherein said contacting occurs in a manner such that compressive and tensile forces experienced by said deposited metal structure substantially cancel each other out so that a stress-free deposited metal structure of said metal compound is produced.

8. The method according to claim 1, wherein said contacting occurs in a manner such that a porous product comprising said metal compound is produced.

9. A composition comprising a metal compound produced according to the method of claim 1.

10. The composition according to claim 9, wherein said composition a stress-free structure having a thickness ranging from about 1 μm to about 100μ.

11. The composition according to claim 9, wherein said composition is a porous composition.

12. The composition according to claim 11, wherein said metal compound is a compound of a metal chosen from aluminum (al), gold (au), silver (ag), copper (cu), iridium (ir), molybdenum (mo), niobium (nb), osmium (os), palladium (pd), platinum (pt), rhenium (re), rhodium (rh), ruthenium (ru), tantalum (ta), titanium (ti) and tungsten (w).

13. The composition according to claim 9, wherein said metal compound is a metal binary compound.

14. The composition according to claim 13, wherein said metal binary compound is a nitride.

15. The composition according to claim 13, wherein said metal binary compound is a carbide.

16. The composition according to claim 9, wherein said metal compound is a metal ternary compound.

17. The composition according to claim 16, wherein said metal ternary compound is a carbonitride.

18. A cathodic arc plasma deposition system comprising:
a cathodic arc plasma source comprising a noble metal cathode;
a deposition chamber; and
a source of a gas in fluid communication with said deposition chamber, wherein said gas is selected from the group consisting of a carbon containing gas and a nitrogen containing gas.

19. The cathodic arc plasma deposition system according to claim 18, wherein said system includes a plasma filter.

20. The cathodic arc plasma deposition system according to claim 18, wherein said system includes a plasma beam biasing element.
